(19) United States
(12) Patent Application Publication
(10) Pub. No.: US 2025/0353965 A1
(43) Pub. Date: Nov. 20, 2025

(54) CURABLE SILICONE COMPOSITION AND CURED PRODUCT THEREOF

(71) Applicant: DOW SILICONES CORPORATION, Midland, MI (US)

(72) Inventors: Yanxia HUANG, Shanghai (CN); Qiang HUANG, Shanghai (CN); Junmin ZHU, Shanghai (CN); Dorab Edul BHAGWAGAR, Auburn, MI (US)

(21) Appl. No.: 18/993,139

(22) PCT Filed: Jul. 11, 2022
(86) PCT No.: PCT/CN2022/104996

§ 371 Date: Jan. 10, 2025

(51) Int. Cl. C08G 77/20; C08G 77/12

(52) U.S. Cl. CPC C08G 77/20; C08G 77/12

(57) ABSTRACT

A curable silicone composition contains (A) a diorganopolysiloxane having two silicon-bonded alkeny groups at both molecular chain terminals; (B) anorganopolysiloxane resin having a silicon-bonded alkenyl group; (C) an organopolysiloxane having a silicon-bonded hydrogen atomand consisting essentially of (c1) a diorganopolysiloxane having silicon-bonded hydrogen atoms at both molecular chain terminals and (c2) an organopolysiloxane resin having a silicon-bonded hydrogen atom; and (D) a hydrosilylation reaction catalyst. The composition can be cured to form a cured product exhibiting excellent adhesion properties against various substrates using for optical devices.

### TECHNICAL FIELD

The present invention relates to a curable silicone composition and a cured product thereof.

### BACKGROUND ART

Curable silicone compositions can be cured to form cured products with high transparency and high elongation, so that they are used as adhesives or pressure sensitive adhesives for improving visibility of optical displays.

For example, Patent Document 1 discloses a curable silicone composition comprising: at least one organopolysiloxane having at least two alkenyl groups in a molecule, at least one organohydrogenpolysiloxane having at least two silicon-bonded hydrogen atoms in a molecule, and a hydrosilylation reaction catalyst.

While, Patent Document 2 discloses a curable silicone composition comprising: a straight chain or partially branched organopolysiloxane having an alkenyl group in a molecule, an resinous organopolysiloxane having an alkenyl group in a molecule, a straight chain or partially branched organohydrogenpolysiloxane having a silicon-bonded hydrogen atom at a molecular chain terminal, an resinous organohydrogenpolysiloxane having a silicon-bonded hydrogen atom in a molecule, and a hydrosilylation reaction catalyst.

However, these curable silicone compositions have a problem in forming cured products exhibiting poor adhesion properties against various substrates using for optical displays.

### PRIOR ART DOCUMENTS

### Patent Documents

Patent Document 1: US Patent Application Publication No. 2014/0150972 A1
Patent Document 2: US Patent Application Publication No. 2022/0002493 A1

### SUMMARY OF THE INVENTION

### Technical Problems

An object of the present invention is to provide a curable silicone composition capable of forming a cured product exhibiting excellent adhesion properties against various substrates using for optical displays, and to further provide a cured product exhibiting excellent adhesion properties.

### Solution to Problem

The curable silicone composition of the present invention comprises:
(A) a diorganopolysiloxane represented by the following general formula:

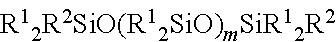

wherein each R¹ is independently an alkyl group with 1 to 12 carbon atoms each R² is independently an alkenyl group with 2 to 12 carbon atoms, and “m” is an integer of from 100 to 1000;
(B) a resinous organopolysiloxane represented by the following average unit formula:

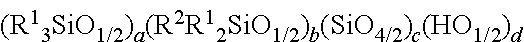

wherein R¹ and R² are as described above, and “a”, “b”, “c” and “d” are numbers satisfying the following conditions: a≥0, b>0, 0.3≤c≤0.7, 0≤d≤0.05, and a+b+c=1, in an amount of from 1.0 to 5.0 parts by mass relative to 100 parts by mass of component (A);
(C) an organopolysiloxane having a silicon-bonded hydrogen atom, in an amount such that a mole ratio of silicon-bonded hydrogen atoms provided by component (C) relative to 1 mol of the alkenyl groups provided by components (A) and (B) is in a range of from 0.5 to 2; and
(D) an effective amount of a hydrosilylation reaction catalyst,
   wherein component (C) an organopolysiloxane consisting essentially of the following components (c1) and (c2):
(c1) a diorganopolysiloxane having silicon-bonded hydrogen atoms at both molecular chain terminals, and
(c2) a resinous organopolysiloxane represented by the following average unit formula:

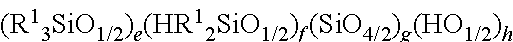

wherein R¹ is as described above, and “e”, “f”, “g” and “h” are numbers satisfying the following conditions: e≤0, f>0, 0.3≤g≤0.7, 0≤h≤0.05, and e+f+g=1, and
wherein a molar ratio of silicon-bonded hydrogen atoms provided by component (c1) per silicon-bonded hydrogen atoms provided by component (c2) is in a range of from 10 to 60.

In various embodiments, the curable silicone composition may further comprise: (E) a hydrosilylation reaction inhibitor, in an amount of from about 0.00001 to about 0.5 parts by mass relative to 100 parts by mass of a total mass of components (A) to (C).

The cured product of the present invention is obtained by curing the curable silicone composition described above.

### Effects of the Invention

The curable silicone composition of the present invention can be cured to form a cured product exhibiting excellent adhesion properties against various substrates using for optical devices. The cured product of the present invention exhibits excellent adhesion properties.

### Definitions

The terms “comprising” or “comprise” are used herein in their broadest sense to mean and encompass the notions of “including,” “include,” “consist(ing) essentially of,” and “consist(ing) of.” The use of “for example,” “e.g.,” “such as,” and “including” to list illustrative examples does not limit to only the listed examples. Thus, “for example” or “such as” means “for example, but not limited to” or “such as, but not limited to” and encompasses other similar or equivalent examples. The term “about” as used herein serves to reasonably encompass or describe minor variations in numerical values measured by instrumental analysis or as a result of sample handling. Such minor variations may be in the order of ±0-25, ±0-10, ±0-5, or ±0-2.5, % of the numerical values. Further, the term “about” applies to both numerical values when associated with a range of values. Moreover, the term “about” may apply to numerical values even when not explicitly stated.

Generally, as used herein a hyphen “-” or dash “-” in a range of values is “to” or “through”; a “>” is “above” or “greater-than”; a “≥” is “at least” or “greater-than or equal to”; a “<” is “below” or “less-than”; and a “≤” is “at most” or “less-than or equal to.” On an individual basis, each of the aforementioned applications for patent, patents, and/or patent application publications, is expressly incorporated herein by reference in its entirety in one or more non-limiting embodiments.

### DETAILED DESCRIPTION OF THE INVENTION

### <Curable Silicone Composition>

First, the curable silicone composition of the present invention will be described in detail.

### <Component (A)>

Component (A) is a diorganopolysiloxane represented by the following general formula:

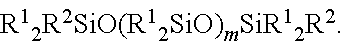

In the formula above, each R¹ is independently an alkyl group with 1 to 12 carbon atoms. Examples of the alkyl groups include methyl groups, ethyl groups, propyl groups, butyl groups and octyl groups, among these, methyl groups are preferable.

In the formula above, each R² is independently an alkenyl group with 2 to 12 carbon atoms. Examples of the alkenyl groups include vinyl groups, allyl groups, butenyl groups, pentenyl groups, hexenyl groups, heptenyl groups, octenyl groups, nonenyl groups, decenyl groups, undecenyl groups and dodecenyl groups, among these, vinyl groups are preferable.

In the formula above, “m” is an integer of from 100 to 1000, alternatively an integer of from 100 to 800. This is because when “m” is greater than or equal to the lower limit of the range described above, mechanical properties of the resulting cured product are sufficiently, while when it is less than or equal to the upper limit of the range described above, the resulting composition has a suitable viscosity in processing and handling.

A viscosity at 25° C. of component (A) is not limited, but it is typically in a range of from about 100 mPa·s to about 100,000 mPa·s, alternatively in a range of from about 200 mPa·s to about 50,000 mPa·s, alternatively in a range of from about 300 mPa·s to about 50,000 mPa·s. Note that in the present specification, viscosity is the value measured using a type B viscometer according to ASTM D 1084 at 23±2° C.

Component (B) is an organopolysiloxane resin represented by the following average unit formula:

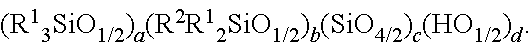

In the formula above, R¹ and R² are as described above. Examples thereof include the same groups as those described above.

In the formula above, “a”, “b”, “c” and “d” are numbers satisfying the following conditions: a≥0, b>0, 0.3≤c≤0.7, 0≤d≤0.05, and a+b+c=1, optionally 0.1≤a≤0.5, 0.01≤b≤0.2, 0.4≤c≤0.7, 0≤d≤0.05, and a+b+c=1, or optionally 0.2≤a≤0.5, 0.01≤b≤0.2, 0.4≤c≤0.7, 0≤d≤0.05, and a+b+c=1. This is because, if “a”, “b”, “c” and “d” are numbers within the ranges mentioned above, a cured product obtained by curing the present composition will have appropriate hardness and mechanical strength.

An amount of component (B) is in a range of from 1.0 to 5.0 parts by mass, alternatively in a range of 1.0 to 3.0 parts by mass relative to 100 parts by mass of component (A). This is because when the amount is greater than or equal to the lower limit of the range described above, mechanical properties of the resulting cured product are sufficiently, while when it is less than or equal to the upper limit of the range described above, the resulting composition has a suitable viscosity in processing and handling.

### <Component (C)>

Component (C) is a crosslinking agent for components (A) and (B) in the present composition and is an organopolysiloxane having a silicon-bonded hydrogen atom and consisting essentially of the following components (c1) and (c2):
(c1) a diorganopolysiloxane having silicon-bonded hydrogen atoms at both molecular chain terminals, and
(c2) a resinous organopolysiloxane represented by the following average unit formula:

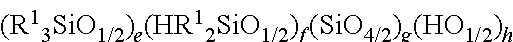

wherein R¹ is as described above, and “e”, “f, “g and “h” are numbers satisfying the following conditions: e≥0, f>0, 0.3≤g≤0.7, 0≤h≤0.05, and e+f+g=1.

Component (c1) functions as a chain length extender in a hydrosilylation reaction with components (A) and (B) and improves flexibility of the cured product. Examples of groups bonding to silicon atoms other than hydrogen atoms in component (c1) include alkyl groups with 1 to 12 carbon atoms such as methyl groups, ethyl groups, propyl groups, butyl groups, pentyl groups, hexyl groups, heptyl groups, octyl groups, nonyl groups, decyl groups, undecyl groups, dodecyl groups, and the like; aryl groups with 6 to 20 carbon atoms such as phenyl groups, tolyl groups, xylyl groups, and the like; aralkyl groups with 7 to 20 carbon atoms such as benzyl groups, phenethyl groups, and the like; and halogen substituted alkyl groups with 1 to 12 carbon atoms such as 3-chloropropyl groups, 3,3,3-trifluoropropyl groups, and the like. Methyl groups are preferable from the perspective of economic efficiency and heat resistance.

Examples of such component (c1) include a dimethylpolysiloxane capped at both molecular chain terminals with dimethylhydrogensiloxy groups, a copolymer of dimethylsiloxane and methylphenylsiloxane capped at both molecular chain terminals with dimethylhydrogensiloxy groups, and mixtures of two or more types thereof.

Component (c2) functions as a crosslinker in a hydrosilylation reaction with components (A) and (B) and improves mechanical properties of the cured product.

In the formula of component (c2), each R¹ is independently an alkyl group with 1 to 12 carbon atoms. Examples of the alkyl groups are as mentioned above. Among them, methyl groups are preferable from the perspective of economic efficiency and heat resistance.

In the formula of component (c2), “e”, “f”, “g” and “h” are numbers satisfying the following conditions: e≥0, f>0, 0.3≤g≤0.7, 0≤h≤0.05, and e+f+g=1, optionally 0≤e≤0.3, 0.1≤f≤0.7, 0.3≤g≤0.6, 0≤h≤0.05, and e+f+g=1, or optionally 0≤e≤0.1, 0.3≤f≤0.7, 0.3≤g≤0.6, 0≤h≤0.01, and e+f+g=1. This is because, if “e”, “f, “g” and “h” are numbers within the ranges mentioned above, a cured product obtained by curing the present composition will have appropriate hardness and mechanical strength.

A molar ratio of silicon-bonded hydrogen atoms provided by component (c1) per silicon-bonded hydrogen atoms provided by component (c2) is in a range of from 10 to 60. This is because when the molar ratio is greater than or equal to the lower limit of the range described above, modulus of the resulting cured product is sufficiently, while when it is less than or equal to the upper limit of the range described above, mechanical properties of the resulting cured product are sufficiently.

An amount of component (C) is an amount such that a molar ratio of silicon-bonded hydrogen atoms provided by component (C) relative to 1 mol of alkenyl groups provided by components (A) and (B) is in a range of from 0.5 to 2, alternatively, in a range of from 0.8 to 2, or alternatively in a range of from 0.5 to 1.5. This is because if the amount is greater than or equal to the lower limit of the range described above, an obtained composition will be sufficiently cured. However, on the other hand, if it is less than or equal to the upper limit of the range described above, the mechanical properties of an obtained cured product will be enhanced.

### <Component (D)>

Component (D) is a hydrosilylation reaction catalyst for promoting the curing of the present composition. Examples thereof include platinum-based catalysts, rhodium-based catalysts, and palladium-based catalysts, and platinum-based catalysts are preferable. Examples of the platinum-based catalyst include platinum fine powder, platinum black, platinum supporting silica fine powder, platinum supporting activated carbon, chloroplatinic acid, alcohol solutions of chloroplatinic acid, olefin complexes of platinum, and alkenylsiloxane complexes of platinum.

An amount of component (D) is an effective amount that promotes the curing of the present composition and is specifically an amount in which the platinum atoms in the catalyst are within a range of from about 0.1 to about 1,000 ppm, alternatively with a range of from about 1 to about 500 ppm in mass units with respect to the present composition. This is because when the content of component (D) is greater than or equal to the lower limit of the range described above, the curing of the resulting composition progresses, while when the content is less than or equal to the upper limit of the range described above, the resulting cured product becomes less susceptible to discoloration.

### <Component (E)>

The present composition may also comprise (E) a hydrosilylation reaction inhibitor in order to control the crosslinking reactions thereof. Examples of component (E) include: alkyne alcohols such as 1-ethynylcyclohexan-1-ol, 2-methyl-3-butyn-2-ol, 3,5-dimethyl-1-hexyn-3-ol, and 2-phenyl-3-butyn-2-ol; enyne compounds such as 3-methyl-3-penten-1-yne and 3,5-dimethyl-3-hexen-1-yne; methyl alkenyl siloxane oligomers such as 1,3,5,7-tetramethyl-1,3,5,7-tetravinylcyclotetrasiloxane and 1,3,5,7-tetramethyl-1,3,5,7-tetrahexenylcyclotetrasiloxane; alkynoxysilanes such as dimethyl bis(3-methyl-1-butyn-3-oxy)silane and methylvinyl bis(3-methyl-1-butyn-3-oxy)silane; alkyneoxysilane compounds such as methyl tris(1-methyl-1-phenyl-propyneoxy)silane, dimethyl bis(1-methyl-1-phenyl-propyneoxy)silane, methyl tris(1,1-dimethyl-propyneoxy)silane, dimethyl bis(1,1-dimethyl-propyneoxy)silane; triazoles, phosphines, mercaptans, hydrazines, sulphoxides, phosphates, nitriles, hydroperoxides, amines, ethylenically unsaturated isocyanates, fumarates (e.g., dialkyl fumarates, dialkenyl fumarates, and/or dialkoxyalkyl fumarates), maleates (e.g., diallyl maleates), alkenes, and combinations thereof.

An amount of component (E) is not limited, and from the perspective of imparting sufficient pot-life to the present composition, it is typically in a range of from about 0.00001 to about 0.5 parts by mass, alternatively in a range of from about 0.0001 to about 0.5 parts by mass, or alternatively in a range of from about 0.0001 to about 0.1 parts by mass, with respect to 100 parts by mass of a total mass of components (A) to (C). This is because when the amount of component (E) is greater than or equal to the lower limit of the range described above, the pot-life of the present composition is sufficiently for use, while when the content is less than or equal to the upper limit of the range described above, the curability of the present composition is good for use.

### <Other Components>

The present composition may contain an adhesion promoter, an antioxidant, a reactive diluent, a leveling agent, a filler, an antistatic agent, an antifoaming agent, a pigment, or the like within a range that does not impair the object of the present invention.

### <Cured Product>

Next, the cured product of the present invention will be described in detail.

The cured product can be obtained by curing the curable silicone composition described above. Hardness of the cured product is not limited, but it typically has a ¼ cone penetration of from 20 to 90 as measured using Penetrometer specified in ASTM D1403. This is because when its penetration is greater than or equal to the lower limit of the range described above, the cured product may have good peel strength, while when it is less than or equal to the upper limit of the range described above, the cured product may have good mechanical properties.

While the shape of the cured product is not limited, examples thereof include sheets, films, tapes, and lumps. Furthermore, integrating with various types of substrates is also possible.

### EXAMPLES

The curable silicone composition and the cured product of the present invention will be described in further detail hereinafter using Practical and Comparative Examples. However, the present invention is not limited to the Examples that follow. Note that in the formulas, Me and Vi represent a methyl group and a vinyl group, respectively. Viscosity of the organopolysiloxane was measured as follows.

### <Viscosity>

Viscosity at 23±2° C. was measured by using a type B viscometer (Brookfield HADVIII Type Rotational Viscometer with using RV-03, 10 rpm, 2 min) according to ASTM D 1084 “Standard Test Methods for Viscosity of Adhesive

### <Penetration>

A curable silicone composition with a thickness of 10 mm or more was left to stand to cure for 40 minutes at 120° C. in an aluminum dish, and the degree of ¼ cone penetration at 25° C. was measured using Anton Paar Penetrometer PNR 12 manufactured by Anton Paar GmbH.

### <180° Peel Strength>

A curable silicone composition with a thickness of 1 mm and a width of 25 mm was left to stand to cure for 30 minutes at 60° C. between a glass sheet and a PET film, and then to post-cure for 3 days at 25° C. 180° peel strength was measured at a peel speed of 305 mm/min.

### <Cohesive Failure>

After measuring 180° peel strength, cohesive failure of cured product to the glass sheet and the PET film.

### <Haze and Transmittance>

A curable silicone composition with a thickness of 1 mm was left to stand to cure for 40 minutes at 70° C. on a glass sheet, and then to post-cure for 3 days at 25° C. Haze and transmittance at 25° C. of a cured product was measured by Spectrophotometer CM-5 manufactured by Konica Minoluta company.

<Haze and Transmittance after a High Temperature/High Humidity Test>

The cured product mentioned above on a glass sheet was subjected to a 85° C./85% RH condition for 3 days and then cooled down. Haze and transmittance at 25° C. of a cured product after a high temperature/high humidity test was measured by Spectrophotometer CM-5 manufactured by Konica Minoluta company.

### Practical Examples 1-6 and Comparative Examples 1-3

Curable silicone compositions shown in Table 1 were prepared using the components mentioned below. Firstly, components (A), (B) and (D) were mixed homogeneously. Next, components (C) and (E) were added to produce curable silicone compositions. The resulting cured products were evaluated as mentioned above. These results are given in Table 1. The “SiH/Vi ratio” in Table 1 indicates a molar ratio of silicon-bonded hydrogen atoms provided by component (C) relative to vinyl groups provided by components (A) and (B). And the “SiH ratio” in Table 1 indicates a molar ratio of silicon-bonded hydrogen atoms provided by component (c1) relative to silicon-bonded hydrogen atoms provided by component (c2).

The following components were used as component (A).
component (a-1): a dimethylpolysiloxane having a vinyl group content of 0.21 mass % and a visc osity of 2400 mPa·s, and represented by the following formula:

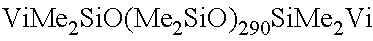

component (a-2): a dimethylpolysiloxane having a vinyl group content of 0.14 mass % and a visc osity of 9600 mPa·s, and represented by the following formula:

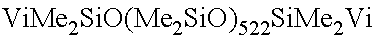

The following component was used as component (B).
component (b-1): an organopolysiloxane resin having a vinyl group content of 1.8 mass % and re presented by the following average unit formula:

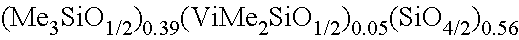

The following components were used as component (C).
component (c-1): a dimethylpolysiloxane having a silicon-bonded hydrogen atom content of 0.14 mass % and represented by the following formula:

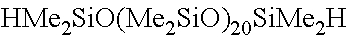

component (c-2): a resinous organopolysiloxane having a silicon-bonded hydrogen atom content of 1.0 mass % and represented by the following average unit formula:

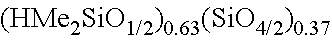

The following component was used as component (D).
component (e-1): A solution of Pt-1,3-divinyl-1,1,3,3-tetramethyldisiloxane complex in 1,3-divinyl-1,1,3,3-tetramethyldisiloxane (Pt content in the solution is 0.9 mass %)

The following component was used as component (E).
component (e-1): A mixture containing 3 mass % of 1-ethynyl-cyclohexan-1-ol and 97 mass % of a dimethylpolysiloxane having a vinyl group content of 0.21 mass % and a viscosity of 430 mPa s, and represented by the following formula:

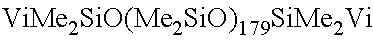

TABLE 1

| | | | Practical Examples | | | | |
|---|---|---|---|---|---|---|---|
| | | | 1 | 2 | 3 | 4 | 5 |
| Curable Silicone | (A) | (a-1) | 62.59 | 57.59 | 63.25 | 63.75 | 62.61 |
| Composition | | (a-2) | 30.00 | 35.00 | 30.00 | 30.00 | 30.00 |
| (parts by mass) | (B) | (b-1) | 2.17 | 2.17 | 1.55 | 1.55 | 2.17 |
| | (C) | (c-1) | 5.00 | 5.00 | 5.00 | 4.50 | 5.00 |
| | | (c-2) | 0.045 | 0.045 | 0.045 | 0.045 | 0.035 |
| | (D) | (d-1) | 0.045 | 0.045 | 0.045 | 0.045 | 0.045 |
| | (E) | (e-1) | 0.015 | 0.015 | 0.015 | 0.015 | 0.015 |

| SiH/Vi ratio | | 0.91 | 0.93 | 0.97 | 0.88 | 0.89 |
|---|---|---|---|---|---|---|
| SiH ratio | | 15.6 | 15.6 | 15.6 | 14.0 | 28.0 |
| Cured Product | Penetration | 48 | 30 | 42 | 73 | 56 |
| | 180° peel strength (N) | 23.5 | 23.3 | 29.0 | 11.3 | 9.6 |
| | Cohesive failure on Glass (%) | 100 | 100 | 100 | 100 | 100 |
| | Cohesive failure on PET (%) | 100 | 100 | 100 | 100 | 100 |
| | Haze | | | | | |
| | Initial | 0.07 | 0.07 | 0.07 | 0.07 | 0.07 |
| | After 85° C./85% RH | 0.15 | 0.15 | 0.15 | 0.15 | 0.15 |
| | Transmittance (%) | | | | | |
| | Initial | 99.7 | 99.7 | 99.7 | 99.7 | 99.7 |
| | After 85° C./85% RH | 99.9 | 99.9 | 99.9 | 99.9 | 99.9 |

| | | | Practical | | | |
|---|---|---|---|---|---|---|
| | | | Examples | Comparative Examples | | |
| | | | 6 | 1 | 2 | 3 |
| Curable Silicone | (A) | (a-1) | 62.12 | 59.77 | 62.56 | 61.60 |
| Composition | | (a-2) | 30.00 | 30.00 | 30.00 | 30.00 |
| (parts by mass) | (B) | (b-1) | 2.17 | 0.62 | 2.17 | 3.10 |
| | (C) | (c-1) | 5.50 | 4.50 | 5.00 | 5.00 |
| | | (c-2) | 0.015 | 0.0075 | 0.075 | 0.045 |
| | (D) | (d-1) | 0.045 | 0.045 | 0.045 | 0.045 |
| | (E) | (e-1) | 0.015 | 0.015 | 0.015 | 0.015 |

| SiH/Vi ratio | | 0.97 | 0.92 | 0.94 | 0.83 |
|---|---|---|---|---|---|
| SiH ratio | | 51.3 | 84.0 | 9.3 | 15.6 |
| Cured Product | Penetration | 35 | 97 | 28 | 60 |
| | 180° peel strength (N) | 25.4 | 0 | 28.5 | 10.6 |
| | Cohesive failure on Glass (%) | 100 | 0 | 100 | 10 |
| | Cohesive failure on PET (%) | 100 | 0 | 33 | 100 |
| | Haze | | | | |
| | Initial | 0.07 | 0.07 | 0.07 | 0.07 |
| | After 85° C./85% RH | 0.15 | 0.15 | 0.15 | 0.15 |
| | Transmittance (%) | | | | |
| | Initial | 99.7 | 99.7 | 99.7 | 99.7 |
| | After 85° C./85% RH | 99.9 | 99.9 | 99.9 | 99.9 |

### INDUSTRIAL APPLICABILITY

The curable silicone composition of the present invention has excellent curability and cures to form a cured product exhibiting excellent adhesive properties against various substrates using for optical devices. Therefore, the curable silicone composition is useful as an adhesive and pressure sensitive adhesive for use in displaying devices such as optical displays and the like (including touch panels) and optical semiconductor devices (including Micro LEDs).

1. A curable silicone composition comprising:
(A) a diorganopolysiloxane represented by the following general formula: 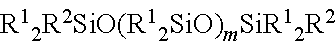
wherein each R¹ is independently an alkyl group with 1 to 12 carbon atoms, each R² is independently an alkenyl group with 2 to 12 carbon atoms, and “m” is an integer of from 100 to 1000;
(B) a resinous organopolysiloxane represented by the following average unit formula: 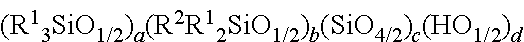
wherein R¹ and R² are as described above, and “a”, “b”, “c” and “d” are numbers satisfying the following conditions: a≥0, b≥0, 0.3≤c≤0.7, 0≤d≤0.05, and a+b+c=1, in an amount of from 1.0 to 5.0 parts by mass relative to 100 parts by mass of component (A);
(C) an organopolysiloxane having a silicon-bonded hydrogen atom, in an amount such that a mole ratio of silicon-bonded hydrogen atoms provided by component (C) relative to 1 mol of the alkenyl groups provided by components (A) and (B) is in a range of from 0.5 to 2; and
(D) an effective amount of a hydrosilylation reaction catalyst,
wherein component (C) an organopolysiloxane consisting essentially of the following components (c1) and (c2):
(c1) a diorganopolysiloxane having silicon-bonded hydrogen atoms at both molecular chain terminals, and
(c2) a resinous organopolysiloxane represented by the following average unit formula: 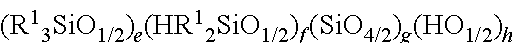
wherein R¹ is as described above, and “e”, “f”, “g” and “h” are numbers satisfying the following conditions: e≥0, f>0, 0.3≤g≤0.7, 0≤h≤0.05, and e+f+g=1, and
wherein a molar ratio of silicon-bonded hydrogen atoms provided by component (c1) per silicon-bonded hydrogen atoms provided by component (c2) is in a range of from 10 to 60.

2. The curable silicone composition according to claim 1, further comprising: (E) a hydrosilylation reaction inhibitor, in an amount of from about 0.00001 to about 0.5 parts by mass relative to 100 parts by mass of a total mass of components (A) to (C).

3. A cured product obtained by curing the curable silicone composition according to claim 1.

4. A cured product obtained by curing the curable silicone composition according to claim 2.
